(19) United States
(12) Patent Application Publication
(10) Pub. No.: US 2026/0160827 A1
(43) Pub. Date: Jun. 11, 2026

(54) APPARATUS AND METHOD FOR DETECTING FAULT OF BATTERY

(71) Applicant: SAMSUNG SDI CO., LTD., Yongin-si (KR)

(72) Inventors: Heejoong KIM, Yongin-si Gyeonggi-do (KR); Sungju NAM, Yongin-si (KR); Bokhyun KA, Yongin-si (KR); Ji-hoon SON, Yongin-si (KR)

(21) Appl. No.: 19/270,768

(22) Filed: Jul. 16, 2025

(30) Foreign Application Priority Data
Dec. 6, 2024 (KR) 10-2024-0180299

(51) Int. Cl. G01R 31/392; G01R 31/3842; G01R 31/389

(52) U.S. Cl. CPC G01R 31/392; G01R 31/3842; G01R 31/389

(57) ABSTRACT

A battery fault detection apparatus includes a charging/discharging circuit configured to charge and discharge a battery, a voltage measuring circuit configured to measure a voltage, a current measuring circuit configured to measure a current, a memory, and a processor, wherein the processor is configured to calculate a charge quantity based on a current value of a negative electrode plate included in the battery measured through the current measuring circuit, calculate a rate of change of the voltage with respect to the charge quantity based on the charge quantity and a voltage value of the negative electrode plate measured through the voltage measuring circuit, and detect a fault of the battery based on a curve representing a relationship between the rate of change of the voltage with respect to the charge quantity and the charge quantity.

### CROSS-REFERENCE TO RELATED APPLICATION

This present application claims priority to and benefit of Korean Application No. 10-2024-0180299, filed on Dec. 6, 2024, in the Korean Intellectual Property Office, the entire disclosure of which is incorporated by reference herein.

### BACKGROUND

### 1. Field

Embodiments of the present disclosure relate to an apparatus and method for detecting fault of a battery.

### 2. Description of the Related Art

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

The above information disclosed in this Background section is for enhancement of understanding of the background of the present disclosure, and therefore, it may contain information that does not constitute related (or prior) art.

### SUMMARY

Embodiments include a battery fault detection apparatus, including a charging/discharging circuit configured to charge and discharge a battery, a voltage measuring circuit configured to measure a voltage, a current measuring circuit configured to measure a current, a memory, and a processor connected to the charging/discharging circuit, the voltage measuring circuit, the current measuring circuit, and the memory, wherein the processor is configured to in an aging process after charging and discharging the battery through the charging/discharging circuit, when a minute voltage change (dV) is detected, calculate a charge quantity (Q) based on a current value of a negative electrode plate included in the battery measured through the current measuring circuit, calculate a rate of change of the voltage with respect to the charge quantity (dV/dQ) based on the charge quantity and a voltage value of the negative electrode plate measured through the voltage measuring circuit, resulting in a calculated rate of change of the voltage with respect to the charge quantity, and detect a fault of the battery based on a curve (Q-dV/dQ curve) representing a relationship between the rate of change of the voltage with respect to the charge quantity and the charge quantity.

The processor may be further configured to identify a value representing a sharpness of a second peak in a charging curve, and if the value representing the sharpness is less than a predetermined amount, identify the battery as defective.

The processor may be further configured to identify the battery as defective if an ion resistance obtained by measuring Electrochemical Impedance Spectroscopy is less than a predetermined amount.

The processor may be further configured to obtain an image of the battery taken before the aging process and after a pre-charging process of the battery, identify an area of a non-impregnated band of the negative electrode plate in the obtained image, and if the area is less than a predetermined size, identify the battery as defective.

The processor may be further configured to measure a 1S3 capacity of the negative electrode plate in a formation process of the battery, resulting in a measured 1S3 capacity, and if the measured 1S3 capacity is equal to or greater than a predetermined size, identify the battery as defective.

The processor may be further configured to, based on the calculated rate of change of the voltage with respect to the charge quantity, calculate an available Li capacity, an uncharged capacity of the negative electrode plate, and an undischarged capacity of the negative electrode plate, and if the available Li capacity is less than a predetermined first amount, the uncharged capacity of the negative electrode plate is equal to or greater than a predetermined second amount, and the undischarged capacity of the negative electrode plate is less than a predetermined third amount, identify the battery as defective.

The processor may be further configured to measure a charging capacity of the battery and measure a discharging capacity of the battery, calculate an efficiency of the battery based on the charging capacity of the battery and the discharging capacity of the battery, and if the efficiency of the battery is equal to or greater than a predetermined amount, identify the battery as defective.

The processor may be further configured to in a discharging curve, identify a value representing a sharpness of a peak that occurs after a peak caused by silicon manifestation, and if the value representing the sharpness is equal to or greater than a predetermined amount, identify the battery as defective.

The processor may be further configured to, when charging of the battery is completed, measure a maximum charging voltage of the negative electrode plate, resulting in a measured maximum charging voltage, and if the measured maximum charging voltage is equal to or greater than a predetermined amount, identify the battery as defective.

The processor may be further configured to, when discharging of the battery is completed, measure a quantity of electric charges released in a discharging process, resulting in a measured quantity of electric charges, identify an available Si capacity based on the measured quantity of electric charges, and if the available Si capacity is equal to or greater than a predetermined amount, identify the battery as defective.

Embodiments include a method for detecting fault of a battery, the method including, in an aging process after charging and discharging the battery through a charging/discharging circuit, when a minute voltage change (dV) is detected, calculating a charge quantity (Q) based on a current value of a negative electrode plate included in the battery measured through a current measuring circuit, calculating a rate of change of a voltage with respect to the charge quantity (dV/dQ) based on the charge quantity and a voltage value of the negative electrode plate measured through a voltage measuring circuit, resulting in a calculated rate of change of the voltage with respect to the charge quantity, and detecting a fault of the battery based on a Q-dV/dQ curve representing a relationship between the rate of change of the voltage with respect to the charge quantity and the charge quantity.

Detecting the fault of the battery may include identifying a value representing a sharpness of a second peak in a charging curve, and identifying the battery as defective if the value representing the sharpness is less than a predetermined amount.

The method for detecting fault of a battery may further include identifying the battery as defective if an ion resistance obtained by measuring Electrochemical Impedance Spectroscopy is less than a predetermined amount.

The method for detecting fault of a battery may further include, before an aging process and after a pre-charging process of the battery, obtaining an image of the battery, identifying an area of a non-impregnated band of the negative electrode plate in the image, and identifying the battery as defective if the area is less than a predetermined size.

The method for detecting fault of a battery may further include measuring a 1S3 capacity of the negative electrode plate in a formation process of the battery, resulting in a measured 1S3 capacity, and identifying the battery as defective if the measured 1S3 capacity is equal to or greater than a predetermined amount.

The method for detecting fault of a battery may further include calculating an available Li capacity, an uncharged capacity of the negative electrode plate, and an undischarged capacity of the negative electrode plate based on the calculated rate of change of the voltage with respect to the charge quantity, and identifying the battery as defective if the available Li capacity is less than a predetermined first amount, the uncharged capacity of the negative electrode plate is equal to or greater than a predetermined second amount, and the undischarged capacity of the negative electrode plate is less than a predetermined third amount.

The method for detecting fault of a battery may further include measuring a charging capacity of the battery and a discharging capacity of the battery, calculating an efficiency of the battery based on the charging capacity of the battery and the discharging capacity of the battery, and identifying the battery as defective if the efficiency of the battery is equal to or greater than a predetermined amount.

Detecting the fault of the battery may include identifying a value representing a sharpness of a peak that occurs after a peak caused by silicon manifestation in a discharging curve, and identifying that the battery is defective if the value representing the sharpness is equal to or greater than a predetermined amount.

The method for detecting fault of a battery may further include measuring a maximum charging voltage of the negative electrode plate when charging of the battery is completed, resulting in a measured maximum charging voltage, and identifying the battery as defective if the measured maximum charging voltage is equal to or greater than a predetermined amount.

The method for detecting fault of a battery may further include measuring a quantity of electric charges released during a discharging process when discharging of the battery is completed, resulting in a measured quantity of electric charges, identifying an available Si capacity based on the measured quantity of electric charges, and identifying the battery as defective if the available Si capacity is equal to or greater than a predetermined amount.

These and other aspects and features of the present disclosure will be described in or will be apparent from the following description of embodiments of the present disclosure.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

Features will become apparent to those of ordinary skill in the art by describing in detail exemplary embodiments with reference to the attached drawings, in which:

FIG. 1 illustrates a configuration of a battery defect detection apparatus according to an embodiment of the present disclosure;

FIG. 2 illustrates a diagram for explaining a method of determining whether a negative electrode plate is non-uniform based on a curve representing a relationship between a rate of change of voltage with respect to charge quantity and the charge quantity according to an embodiment of the present disclosure;

FIG. 3 illustrates a diagram for explaining a method of determining whether a negative electrode plate is non-uniform based on an area of a non-impregnated band of the negative electrode plate according to an embodiment of the present disclosure;

FIG. 4 illustrates a diagram for explaining a method of detecting a fault of a battery based on a difference in the amount of film formation on an electrode plate according to an embodiment of the present disclosure;

FIG. 5 illustrates a diagram for explaining a method of determining the amount of film formation based on a 1S3 capacity of a negative electrode plate according to an embodiment of the present disclosure;

FIG. 6 illustrates a diagram for explaining a method of determining the amount of film formation based on an uncharged capacity and an undischarged capacity of a negative electrode plate according to an embodiment of the present disclosure;

FIG. 7 illustrates a diagram for explaining a method of determining the amount of film formation based on an efficiency of a battery according to an embodiment of the present disclosure;

FIG. 8 illustrates a diagram for explaining a method of identifying a difference in silicon charge depth based on a fully charged negative electrode potential according to an embodiment of the present disclosure;

FIG. 9 illustrates a diagram for explaining a method of identifying a difference in silicon charge depth based on an available Si capacity according to an embodiment of the present disclosure;

FIG. 10 illustrates a diagram for explaining a method of identifying a difference in silicon charge depth based on a curve representing a relationship between a rate of change of voltage with respect to charge quantity and the charge quantity according to an embodiment of the present disclosure; and

FIG. 11 illustrates a method for detecting a fault of a battery according to an embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her disclosure in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. §132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

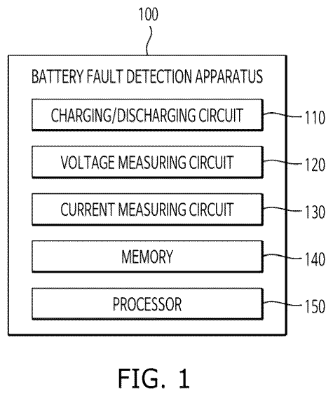

FIG. 1 illustrates a configuration of a battery defect detection apparatus according to an embodiment of the present disclosure. Referring to FIG. 1, a battery fault detection apparatus 100 may detect a defect of a battery by checking a minute voltage change (dV) of the battery in a formation process. At this time, the battery fault detection apparatus 100 may discriminate/select whether the minute voltage change is caused by an internal short-circuit defect of a battery cell (hereinafter referred to as a true defect) caused by a metallic foreign substance, or caused by other factors (hereinafter referred to as a false defect), such as negative electrode charge depth or a non-uniform reaction. Then, the battery fault detection apparatus 100 may identify the battery as a normal battery if the minute voltage change is due to a false defect, and identify the battery as a defective battery only if the minute voltage change is due to a true defect.

The battery fault detection apparatus 100 may include a charging/discharging circuit 110, a voltage measuring circuit 120, a current measuring circuit 130, a memory 140, and a processor 150. However, the battery fault detection apparatus 100 may omit at least one of the above components, or may further include at least one other component. In one example, the battery fault detection apparatus 100 may further include a communication circuit (or communication module) for communicating with an external electronic device. In another example, the battery fault detection apparatus 100 may further include a display for displaying a visual object indicating whether the battery is defective, an output device for outputting sound/vibration indicating whether the battery is defective, etc.

The charging/discharging circuit 110 may charge or discharge the battery. For example, the charging/discharging circuit 110 may be electrically connected to the battery and may charge the battery to a predetermined voltage or discharge the battery to a predetermined voltage.

The voltage measuring circuit 120 may be electrically connected to the battery and may measure a voltage of the battery. For example, the voltage measuring circuit 120 may detect a voltage value of a negative electrode plate included in the battery.

The current measuring circuit 130 may be electrically connected to the battery and may measure a current of the battery. For example, the current measuring circuit 130 may detect a current value of a negative electrode plate included in the battery.

The memory 140 may store various data used by at least one component (e.g., processor 150) of the battery fault detection apparatus 100. The data may include, for example, input data or output data regarding software (or a program) and related instructions. The memory may include volatile memory or non-volatile memory.

The processor 150 may be connected to the charging/discharging circuit 110, the voltage measuring circuit 120, the current measuring circuit 130, and the memory 140, and may be configured to execute at least one program included in the memory 140 that is computer-readable. For example, by executing software (or a program), the processor 150 may control at least one other component (e.g., hardware or software components) of the battery fault detection apparatus 100 connected to the processor 150, and may perform various data processing or operations. According to an embodiment, as at least part of the data processing or operations, the processor 150 may load a command or data received from another component (e.g., the voltage measuring circuit 120 or the current measuring circuit 130) into the volatile memory, process the command or data stored in the volatile memory, and store result data in the non-volatile memory.

At least one program executed by the processor 150 may include instructions associated with detecting a fault of the battery. Hereinafter, for convenience of explanation, it will be described that the processor 150 performs certain functions, but this is only for ease of description, and it will be understood that the functions performed by the processor 150 are essentially performed by the processor 150 executing at least one program stored in the memory 140.

In connection with detecting a fault of the battery, the processor 150 may, in an aging process after charging and discharging the battery through the charging/discharging circuit 110, when a minute voltage change is detected, determine whether the minute voltage change is due to a true defect or a false defect.

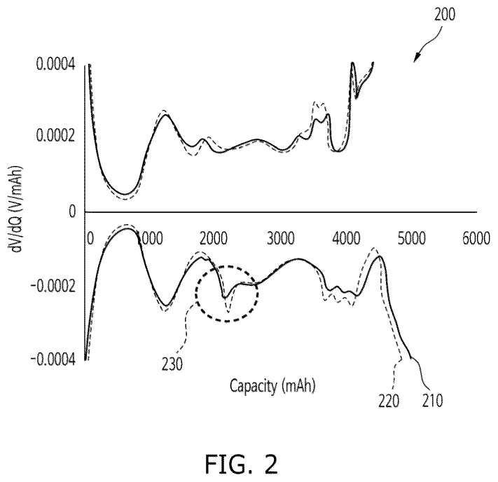

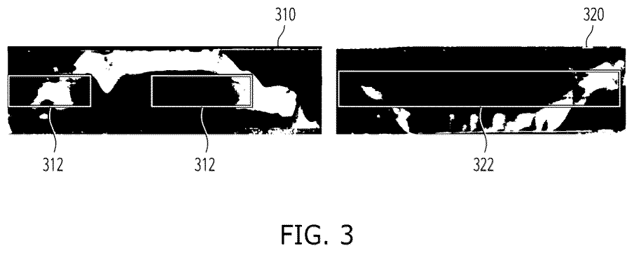

According to an embodiment, the processor 150 may, in an aging process after charging and discharging the battery through the charging/discharging circuit 110, when a minute voltage change is detected, determine whether the negative electrode plate is non-uniform. Then, if the processor 150 determines that the negative electrode plate is non-uniform, the processor 150 may determine that the minute voltage change is caused by the non-uniformity of the negative electrode plate, i.e., a false defect, and thus not treat the battery as defective. Also, if the processor 150 determines that the negative electrode plate is uniform, the processor 150 may determine that the minute voltage change is caused by a true defect and treat the battery as defective. A method by which the processor 150 determines whether the negative electrode plate is non-uniform will be described in detail with reference to FIGS. 2 and 3.

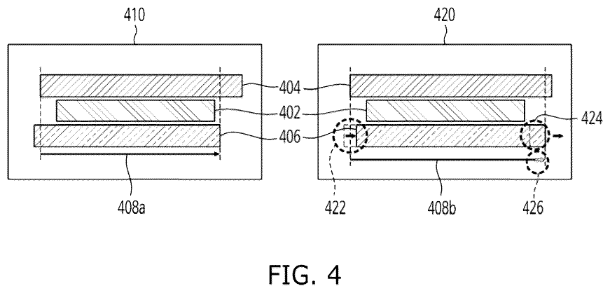

According to an embodiment, the processor 150 may, in an aging process after charging and discharging the battery through the charging/discharging circuit 110, when a minute voltage change is detected, identify a difference in the amount of film formation on an electrode plate. Then, if the processor 150 identifies that the amount of film formation is less than a predetermined size (e.g., predetermined amount), the processor 150 may determine that the minute voltage change is caused by insufficient film formation, i.e., a false defect, and thus not treat the battery as defective. Also, if the processor 150 identifies that the amount of film formation is equal to or greater than a predetermined size (e.g., predetermined amount), the processor 150 may determine that the minute voltage change is caused by a true defect and treat the battery as defective. A method by which the processor 150 identifies a difference in the amount of film formation on an electrode plate will be described in detail with reference to FIGS. 4 through 7.

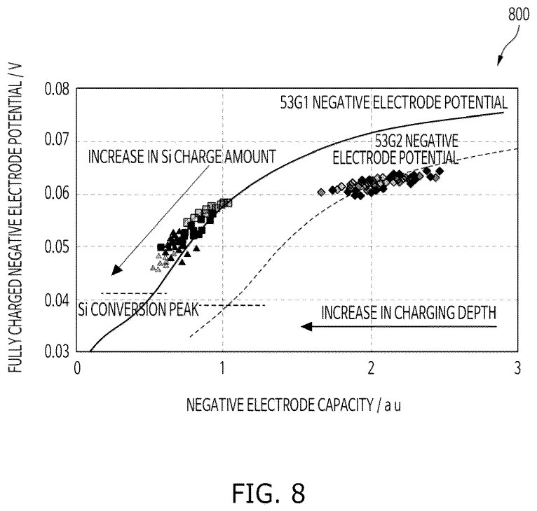

According to an embodiment, the processor 150 may, in an aging process after charging and discharging the battery through the charging/discharging circuit 110, when a minute voltage change is detected, identify a difference in silicon charge depth. Then, if the processor 150 identifies that the silicon charge depth is equal to or greater than a predetermined size (e.g., predetermined amount), the processor 150 may determine that the minute voltage change is caused by a high silicon charge depth, i.e., a false defect, and thus not treat the battery as defective. Also, if the processor 150 identifies that the silicon charge depth is less than a predetermined size, the processor 150 may determine that the minute voltage change is caused by a true defect and treat the battery as defective. A method by which the processor 150 identifies a difference in silicon charge depth will be described in detail with reference to FIGS. 8 through 10.

FIG. 2 illustrates a diagram for explaining a method of determining whether a negative electrode plate is non-uniform based on a curve representing a relationship between a rate of change of voltage with respect to charge quantity and the charge quantity according to an embodiment of the present disclosure. Referring to FIG. 2, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may determine whether the negative electrode plate is non-uniform. In FIG. 2, it will be described that the processor determines whether the negative electrode plate is non-uniform based on a curve (Q-dV/dQ curve) 200 representing a relationship between a rate of change of the voltage with respect to charge quantity (dV/dQ) and the charge quantity (Q).

First, the processor may calculate the charge quantity based on a current value of the negative electrode plate measured through the current measuring circuit (e.g., current measuring circuit 130 of FIG. 1). Then, the processor may calculate the rate of change of the voltage with respect to the charge quantity based on the charge quantity and a voltage value of the negative electrode plate measured through the voltage measuring circuit (e.g., voltage measuring circuit 120 of FIG. 1). Then, based on the curve 200 that represents a relationship between the rate of change of the voltage with respect to the charge quantity and the charge quantity, the processor may determine whether the negative electrode plate is non-uniform.

According to an embodiment, the processor may identify a value representing the sharpness of a second peak 230 in a charging curve (the lower curve in FIG. 2) among the curve 200 that represents the relationship between the rate of change of the voltage with respect to the charge quantity and the charge quantity. For example, the processor may identify a value representing the sharpness of the second peak 230 by using the slope change at the second peak 230, the width of the second peak 230, and so on. Then, if the value representing the sharpness is equal to or greater than a predetermined size, as shown in the second curve 220, the processor may determine that the negative electrode plate is non-uniform. In this case, the processor may determine that the minute voltage change is caused by the non-uniformity of the negative electrode plate, i.e., a false defect, and thus may not treat the battery as defective. Also, if the value representing the sharpness is less than a predetermined size, as shown in the first curve 210, the processor may determine that the negative electrode plate is uniform. In this case, the processor may determine that the minute voltage change is caused by a true defect and treat the battery as defective.

FIG. 3 illustrates a diagram for explaining a method of determining whether a negative electrode plate is non-uniform based on an area of a non-impregnated band of the negative electrode plate according to an embodiment of the present disclosure. Referring to FIG. 3, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may determine whether the negative electrode plate is non-uniform. In FIG. 3, it will be described that the processor determines whether the negative electrode plate is non-uniform based on the area of a non-impregnated band 312, 322 of the negative electrode plate.

First, the processor may obtain an image 310 and an image 320 of the battery, taken before an aging process and after a pre-charging process of the battery. For example, the processor may obtain disassembly photographs of the battery taken by a camera (or other imaging device) before an aging process and after a pre-charging process of the battery. Here, the camera may be included in the battery fault detection apparatus or may be included in an external electronic device. If the camera is included in an external electronic device, the processor may receive the image 310 and the image 320 of the battery from the external electronic device through a communication circuit.

Then, the processor may identify the area of the non-impregnated band 312, 322 of the negative electrode plate in the image 310 and the image 320, respectively. Then, if the area of the non-impregnated band 312, 322 is equal to or greater than a predetermined size, as in the image 320 (e.g., the second image), the processor may determine that the negative electrode plate is non-uniform. In this case, the processor may determine that the minute voltage change is caused by the non-uniformity of the negative electrode plate, i.e., a false defect, and thus may not treat the battery as defective. Also, if the area of the non-impregnated band 312, 322 is less than a predetermined size, as in image 310, the processor may determine that the negative electrode plate is uniform. In this case, the processor may determine that the minute voltage change is caused by a true defect and treat the battery as defective.

According to an embodiment, the processor may determine whether the negative electrode plate is non-uniform based on an ion resistance (Rion) representing the movement resistance of ions within an electrode plate. For example, the processor may obtain the ion resistance by measuring Electrochemical Impedance Spectroscopy (EIS) after fabricating a symmetric cell. Then, if the ion resistance is equal to or greater than a predetermined size (e.g., predetermined amount), the processor may determine that the negative electrode plate is non-uniform. In this case, the processor may determine that the minute voltage change is caused by the non-uniformity of the negative electrode plate, i.e., a false defect, and thus may not treat the battery as defective. Also, if the ion resistance is less than a predetermined size, the processor may determine that the negative electrode plate is uniform. In this case, the processor may determine that the minute voltage change is caused by a true defect and treat the battery as defective.

FIG. 4 illustrates a diagram for explaining a method of detecting a fault of a battery based on a difference in the amount of film formation on an electrode plate according to an embodiment of the present disclosure. Referring to FIG. 4, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in the amount of film formation on an electrode plate. In FIG. 4, a method of detecting a fault of a battery based on the difference in the amount of film formation on an electrode plate will be described.

Comparing a normal state 410 of a battery cell with a defective state 420, there may be a difference in the amount of film formed on the electrode plate 404 and negative electrode plate 406 of the cell 402. In the defective state 420, the amount of film formation during the formation process may be small, so that, after completion of the formation process, the amount of Li within the cell 402 (i.e., an available Li capacity 408b) may be relatively larger compared to the available Li capacity 408a in the normal state 410. Also, if the available Li capacity 408b is large, due to a slippage phenomenon, the uncharged capacity of negative electrode plate 406 may decrease, and the undischarged capacity of negative electrode plate 406 may increase. In addition, a small amount of film formation indicates that a robust film has not formed, so many side reactions may occur, resulting in lower efficiency of the battery.

Accordingly, if the processor identifies that the amount of film formation is less than a predetermined size, the processor may determine that the minute voltage change is caused by insufficient film formation, i.e., a false defect, and thus may not treat the battery as defective. Also, if the processor identifies that the amount of film formation is equal to or greater than a predetermined size, the processor may determine that the minute voltage change is caused by a true defect and treat the battery as defective.

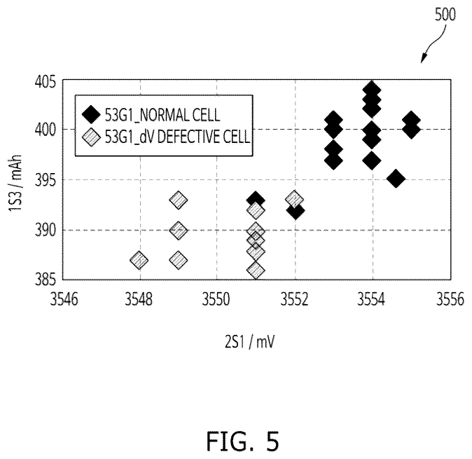

FIG. 5 illustrates a diagram for explaining a method of determining the amount of film formation based on a 1S3 capacity of a negative electrode plate according to an embodiment of the present disclosure. Referring to FIG. 5, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in the amount of film formation on an electrode plate. In FIG. 5, a method of determining the amount of film formation based on a 1S3 capacity of a negative electrode plate will be described.

As described with reference to FIG. 4, during the formation process, a small amount of film formation indicates that the amount of Li consumed in formation is small, which may indicate that the 1S3 capacity is small. Therefore, the processor may measure the 1S3 capacity of the negative electrode plate during the formation process. Here, the 1S3 capacity may represent a third discharge capacity during a first charge/discharge cycle (S) of the formation process, and using the 1S3 capacity, it is possible to check the amount of Li capacity used for film formation in the formation process.

Then, if the measured 1S3 capacity is less than a predetermined size, as shown by the “53G1_dV defective cell” points in graph 500 of FIG. 5, the processor may identify that the amount of film formation is insufficient. In this case, the processor may determine that the minute voltage change is caused by insufficient film formation, i.e., a false defect, and thus may not treat the battery as defective. Also, if the measured 1S3 capacity is equal to or greater than a predetermined size, as shown by the “53G1_normal cell” points in graph 500 of FIG. 5, the processor may identify that the amount of film formation is sufficient. In this case, the processor may determine that the minute voltage change is caused by a true defect and treat the battery as defective.

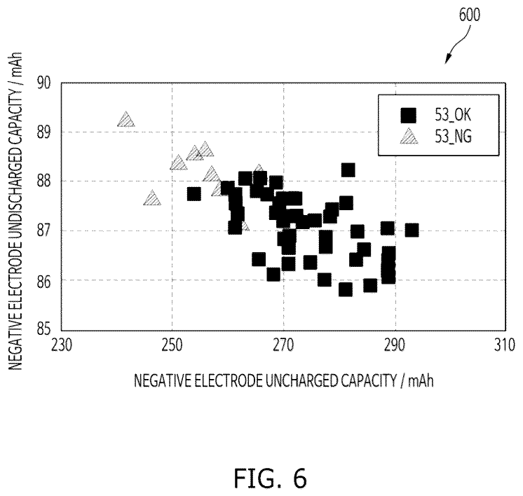

FIG. 6 illustrates a diagram for explaining a method of determining the amount of film formation based on an uncharged capacity and an undischarged capacity of a negative electrode plate according to an embodiment of the present disclosure. Referring to FIG. 6, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in the amount of film formation on an electrode plate. In FIG. 6, a method of determining the amount of film formation based on the uncharged capacity and the undischarged capacity of a negative electrode plate will be described.

As described with reference to FIG. 4, a small amount of film formation in the formation process indicates that the amount of Li in the cell, i.e., the available Li capacity, is large after completion of the formation process, and if the available Li capacity is large, due to a slippage phenomenon, the uncharged capacity of the negative electrode plate decreases and the undischarged capacity of the negative electrode plate increases. Therefore, the processor may calculate the available Li capacity, the uncharged capacity of the negative electrode plate, and the undischarged capacity of the negative electrode plate based on the rate of change of the voltage with respect to the charge quantity (dV/dQ). Then, if the available Li capacity is equal to or greater than a predetermined first size (e.g., predetermined first amount), the uncharged capacity of the negative electrode plate is less than a predetermined second size, and the undischarged capacity of the negative electrode plate is equal to or greater than a predetermined third size, as shown by the “53_NG” points in graph 600 of FIG. 6, the processor may identify that the amount of film formation is insufficient. In this case, the processor may determine that the minute voltage change is caused by insufficient film formation, i.e., a false defect, and thus may not treat the battery as defective. Also, if the available Li capacity is less than the predetermined first size, the uncharged capacity of the negative electrode plate is equal to or greater than the predetermined second size, and the undischarged capacity of the negative electrode plate is less than the predetermined third size, as shown by the “53_OK” points in graph 600 of FIG. 6, the processor may identify that the amount of film formation is sufficient. In this case, the processor may determine that the minute voltage change is caused by a true defect and treat the battery as defective.

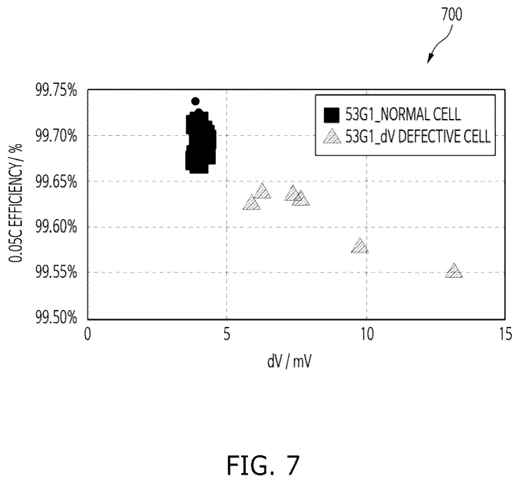

FIG. 7 illustrates a diagram for explaining a method of determining the amount of film formation based on an efficiency of a battery according to an embodiment of the present disclosure. Referring to FIG. 7, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in the amount of film formation on an electrode plate. In FIG. 7, a method of determining the amount of film formation based on the efficiency of a battery will be described.

As described with reference to FIG. 4, a small amount of film formation in the formation process indicates that a robust film has not formed, and thus many side reactions may occur, resulting in lower efficiency of the battery. Therefore, the processor may measure the charging capacity and the discharging capacity of the battery at a predetermined charging/discharging rate (for example, 0.5 C), and based on the charging capacity and the discharging capacity of the battery, may calculate the efficiency of the battery (for example, discharging capacity/charging capacity). Then, if the efficiency of the battery is less than a predetermined size, as shown by the “53G1_dV defective cell” points in graph 700 of FIG. 7, the processor may identify that the amount of film formation is insufficient. In this case, the processor may determine that the minute voltage change is caused by insufficient film formation, i.e., a false defect, and thus may not treat the battery as defective. Also, if the efficiency of the battery is equal to or greater than a predetermined size, as shown by the “53G1_normal cell” points in graph 700 of FIG. 7, the processor may identify that the amount of film formation is sufficient. In this case, the processor may determine that the minute voltage change is caused by a true defect and treat the battery as defective.

FIG. 8 illustrates a diagram for explaining a method of identifying a difference in silicon charge depth based on a fully charged negative electrode potential according to an embodiment of the present disclosure. Referring to FIG. 8, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in silicon charge depth. In FIG. 8, a method by which the processor identifies a difference in silicon charge depth based on the fully charged negative electrode potential will be described.

First, the processor may measure a maximum charging voltage of the negative electrode plate when the battery is fully charged. Here, the maximum charging voltage of the negative electrode plate may represent the fully charged negative electrode potential. Then, if the measured maximum charging voltage (i.e., the fully charged negative electrode potential) is less than a predetermined size, as at points on the “53G1 negative electrode potential” in graph 800 of FIG. 8, the processor may identify that the silicon charge depth is equal to or greater than a predetermined size. In this case, the processor may determine that the minute voltage change is caused by a high silicon charge depth, i.e., a false defect, and thus may not treat the battery as defective. Also, if the measured maximum charging voltage (i.e., the fully charged negative electrode potential) is equal to or greater than a predetermined size, as at points on the “53G2 negative electrode potential” in graph 800 of FIG. 8, the processor may identify that the silicon charge depth is less than a predetermined size. In this case, the processor may determine that the minute voltage change is caused by a true defect and treat the battery as defective.

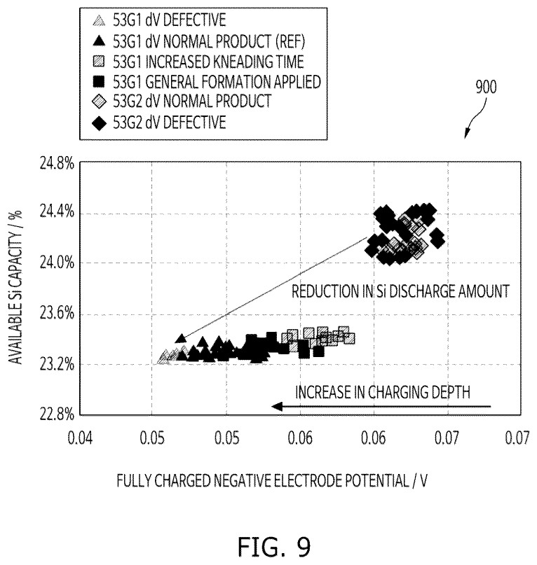

FIG. 9 illustrates a diagram for explaining a method of identifying a difference in silicon charge depth based on an available Si capacity according to an embodiment of the present disclosure. Referring to FIG. 9, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in silicon charge depth. In FIG. 9, a method by which the processor identifies a difference in silicon charge depth based on an available Si capacity will be described.

First, when the battery is fully discharged, the processor may measure the quantity of electric charges released during the discharging process and, based on the measured quantity of electric charges, identify the available Si capacity. Then, if the available Si capacity is less than a predetermined size, as in the “53G1 dV defective” points in graph 900 of FIG. 9, the processor may identify that the silicon charge depth is equal to or greater than a predetermined size. In this case, the processor may determine that the minute voltage change is caused by a high silicon charge depth, i.e., a false defect, and thus may not treat the battery as defective. Also, if the available Si capacity is equal to or greater than a predetermined size, as in the “53G2 dV defective” points in graph 900 of FIG. 9, the processor may identify that the silicon charge depth is less than a predetermined size. In this case, the processor may determine that the minute voltage change is caused by a true defect and treat the battery as defective.

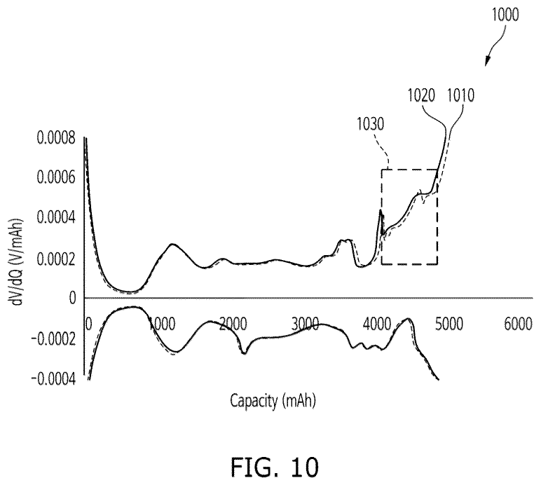

FIG. 10 illustrates a diagram for explaining a method of identifying a difference in silicon charge depth based on a curve representing a relationship between a rate of change of voltage with respect to charge quantity and the charge quantity according to an embodiment of the present disclosure. Referring to FIG. 10, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may identify a difference in silicon charge depth. In FIG. 10, a method by which the processor identifies a difference in silicon charge depth based on a curve (Q-dV/dQ curve) 1000 that represents the relationship between a rate of change of the voltage with respect to charge quantity (dV/dQ) and the charge quantity (Q) will be described.

First, the processor may calculate the charge quantity based on a current value of the negative electrode plate measured through the current measuring circuit (e.g., current measuring circuit 130 of FIG. 1). Then, the processor may calculate the rate of change of the voltage with respect to the charge quantity based on the charge quantity and a voltage value of the negative electrode plate measured through the voltage measuring circuit (e.g., voltage measuring circuit 120 of FIG. 1). Then, based on the curve 1000 that represents a relationship between the rate of change of the voltage with respect to the charge quantity and the charge quantity, the processor may identify a difference in silicon charge depth.

According to an embodiment, in the charging curve (the upper curve in FIG. 10) among the curve 1000 that represents the relationship between the rate of change of the voltage with respect to the charge quantity and the charge quantity, the processor may identify a value representing the sharpness of a peak 1030 that occurs after a peak caused by silicon expression. For example, the processor may identify a value representing the sharpness of peak 1030 by using the slope change at peak 1030, the width of peak 1030, and so on. Then, if the value representing the sharpness is less than a predetermined size, as in the second curve 1020, the processor may identify that the peak 1030 has a broad shape due to Si recrystallization, and identify that the silicon charge depth is equal to or greater than a predetermined size. In this case, the processor may determine that the minute voltage change is caused by a high silicon charge depth, i.e., a false defect, and thus may not treat the battery as defective. Also, if the value representing the sharpness is equal to or greater than a predetermined size, as in the first curve 1010, the processor may identify that the silicon charge depth is less than a predetermined size. In this case, the processor may determine that the minute voltage change is caused by a true defect and treat the battery as defective.

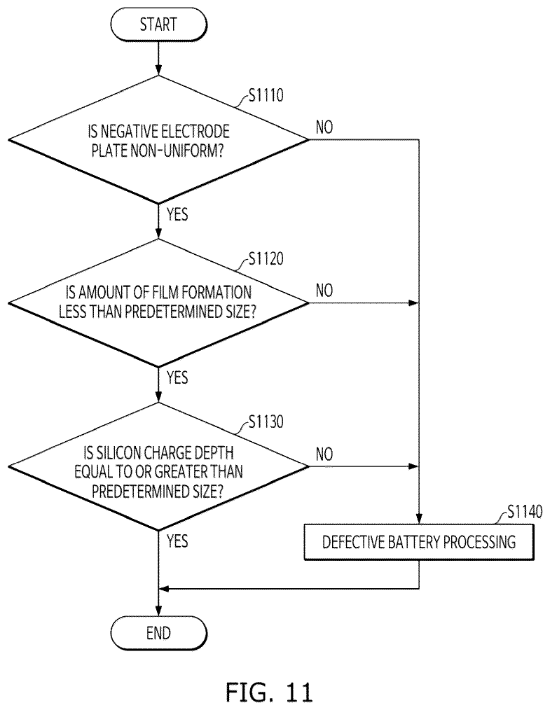

FIG. 11 illustrates a method for detecting a fault of a battery according to an embodiment of the present disclosure. Referring to FIG. 11, in an aging process after charging and discharging the battery through the charging/discharging circuit (e.g., charging/discharging circuit 110 of FIG. 1), if a minute voltage change is detected, the processor (e.g., processor 150 of FIG. 1) of the battery fault detection apparatus (e.g., battery fault detection apparatus 100 of FIG. 1) may determine whether the minute voltage change is due to a true defect or a false defect.

In step S1110, the processor may determine whether the negative electrode plate is non-uniform. According to an embodiment, the processor may determine whether the negative electrode plate is non-uniform based on a curve (Q-dV/dQ curve) that represents the relationship between the rate of change of the voltage (dV/dQ) with respect to the charge quantity (Q). Specifically, the processor may calculate the charge quantity based on a current value of the negative electrode plate measured through the current measuring circuit (e.g., current measuring circuit 130 of FIG. 1). Then, the processor may calculate the rate of change of the voltage with respect to the charge quantity based on the charge quantity and a voltage value of the negative electrode plate measured through the voltage measuring circuit (e.g., voltage measuring circuit 120 of FIG. 1). Then, based on the curve representing the relationship between the rate of change of the voltage with respect to the charge quantity and the charge quantity, the processor may determine whether the negative electrode plate is non-uniform. For example, the processor may identify a value representing the sharpness of a second peak in the charging curve among the curve that represents the relationship between the rate of change of the voltage with respect to the charge quantity and the charge quantity, and if the value representing the sharpness is equal to or greater than a predetermined size, determine that the negative electrode plate is non-uniform, and if the value representing the sharpness is less than a predetermined size, determine that the negative electrode plate is uniform.

According to another embodiment, the processor may determine whether the negative electrode plate is non-uniform based on the area of a non-impregnated band of the negative electrode plate. Specifically, the processor may obtain an image of the battery, taken before an aging process and after a pre-charging process of the battery. Then, the processor may identify the area of the non-impregnated band of the negative electrode plate in the obtained image. Then, if the area of the non-impregnated band is equal to or greater than a predetermined size, the processor may determine that the negative electrode plate is non-uniform, and if the area of the non-impregnated band is less than a predetermined size, the processor may determine that the negative electrode plate is uniform.

According to still another embodiment, the processor may determine whether the negative electrode plate is non-uniform based on an ion resistance representing movement resistance of ions within an electrode plate. Specifically, the processor may measure EIS after fabricating a symmetric cell and obtaining the ion resistance. Then, if the ion resistance is equal to or greater than a predetermined size, the processor may determine that the negative electrode plate is non-uniform, and if the ion resistance is less than a predetermined size, the processor may determine that the negative electrode plate is uniform.

If the negative electrode plate is determined to be non-uniform (YES in S1110), in step S1120, the processor may determine whether the amount of film formation is less than a predetermined size. According to an embodiment, the processor may determine the amount of film formation based on a 1S3 capacity of the negative electrode plate. Specifically, the processor may measure the 1S3 capacity of the negative electrode plate in a formation process. Then, if the measured 1S3 capacity is less than a predetermined size, the processor may identify that the amount of film formation is less than a predetermined size, i.e., that the amount of film formation is insufficient, and if the measured 1S3 capacity is equal to or greater than a predetermined size, the processor may identify that the amount of film formation is equal to or greater than a predetermined size, i.e., that the amount of film formation is sufficient.

According to another embodiment, the processor may determine the amount of film formation based on the uncharged capacity of the negative electrode plate and the undischarged capacity of the negative electrode plate. Specifically, the processor may calculate an available Li capacity, the uncharged capacity of the negative electrode plate, and the undischarged capacity of the negative electrode plate based on the rate of change of the voltage with respect to the charge quantity (dV/dQ). Then, if the available Li capacity is equal to or greater than a predetermined first size, the uncharged capacity of the negative electrode plate is less than a predetermined second size, and the undischarged capacity of the negative electrode plate is equal to or greater than a predetermined third size, the processor may identify that the amount of film formation is less than a predetermined size, i.e., insufficient, and if the available Li capacity is less than the predetermined first size, the uncharged capacity of the negative electrode plate is equal to or greater than the predetermined second size, and the undischarged capacity of the negative electrode plate is less than the predetermined third size, the processor may identify that the amount of film formation is equal to or greater than a predetermined size, i.e., sufficient.

According to still another embodiment, the processor may determine the amount of film formation based on the efficiency of the battery. Specifically, the processor may measure the charging capacity and the discharging capacity of the battery, and based on the charging capacity of the battery and the discharging capacity of the battery, may calculate the efficiency of the battery (for example, discharging capacity/charging capacity). Then, if the efficiency of the battery is less than a predetermined size, the processor may identify that the amount of film formation is less than a predetermined size, i.e., insufficient, and if the efficiency of the battery is equal to or greater than a predetermined size, the processor may identify that the amount of film formation is equal to or greater than a predetermined size, i.e., sufficient.

If the amount of film formation is determined to be less than a predetermined size, i.e., if the amount of film formation is insufficient (YES in S1120), in step S1130, the processor may determine whether the silicon charge depth is equal to or greater than a predetermined size. According to an embodiment, the processor may determine the silicon charge depth based on the fully charged negative electrode potential. Specifically, when the battery is fully charged, the processor may measure the maximum charging voltage (fully charged negative electrode potential) of the negative electrode plate. Then, if the measured maximum charging voltage is less than a predetermined size, the processor may identify that the silicon charge depth is equal to or greater than a predetermined size, and if the measured maximum charging voltage is equal to or greater than a predetermined size, the processor may identify that the silicon charge depth is less than a predetermined size.

According to another embodiment, the processor may determine the silicon charge depth based on an available Si capacity. Specifically, when the battery is fully discharged, the processor may measure the quantity of electric charges released during the discharging process, and based on the measured quantity of electric charges, identify the available Si capacity. Then, if the available Si capacity is less than a predetermined size, the processor may identify that the silicon charge depth is equal to or greater than a predetermined size, and if the available Si capacity is equal to or greater than a predetermined size, the processor may identify that the silicon charge depth is less than a predetermined size.

According to still another embodiment, the processor may determine the silicon charge depth based on a curve (Q-dV/dQ curve) that represents the relationship between the rate of change of the voltage (dV/dQ) with respect to the charge quantity (Q). Specifically, the processor may calculate the charge quantity based on a current value of the negative electrode plate measured through the current measuring circuit. Then, the processor may calculate the rate of change of the voltage with respect to the charge quantity based on the charge quantity and a voltage value of the negative electrode plate measured through the voltage measuring circuit. Then, based on the curve that represents the relationship between the rate of change of the voltage with respect to the charge quantity and the charge quantity, the processor may determine the silicon charge depth. For example, the processor may identify a value representing the sharpness of a peak that occurs after a peak caused by silicon expression in the charging curve among the curve that represents the relationship between the rate of change of the voltage with respect to the charge quantity and the charge quantity. If the value representing the sharpness is less than a predetermined size, the processor may identify that the silicon charge depth is equal to or greater than a predetermined size, and if the value representing the sharpness is equal to or greater than a predetermined size, the processor may identify that the silicon charge depth is less than a predetermined size.

If the silicon charge depth is determined to be equal to or greater than a predetermined size (YES in S1130), the processor may determine that the minute voltage change is due to a false defect and thus may not treat the battery as defective.

If it is determined that the negative electrode plate is uniform (NO in S1110), or if the amount of film formation is equal to or greater than a predetermined size (i.e., sufficient) (NO in S1120), or if the silicon charge depth is less than a predetermined size (NO in S1130), then, in step S1140, the processor may determine that the minute voltage change is due to a true defect and treat the battery as defective.

According to an embodiment, equal to or greater than one of steps S1110, S1120, or S1130 may have its execution order changed (e.g., the execution order of FIG. 11 may change). For example, after step S1110 is performed, step S1130 may be performed, followed by step S1120. In another example, step S1120 may be performed first, followed by steps S1110 and S1130. In yet another example, step S1130 may be performed first, followed by steps S1110 and S1120.

A secondary battery may be given electrical characteristics through a formation process after an assembly process. For example, the battery may form a SEI (Solid Electrolyte Interphase) layer on the negative electrode and the positive electrode through charging and discharging processes. Then, by storing the battery for a predetermined time under a specified temperature or humidity condition in an aging process, the electrolyte inside the battery may sufficiently infiltrate, resulting in an optimized state for ion movement. Then, by analyzing the internal resistance (IR) and open-circuit voltage (OCV) of the battery, the quality of the battery may be evaluated and any defect may be detected.

Regarding defect detection of the battery, to detect an internal short-circuit defect (hereinafter referred to as a true defect) of a battery cell caused by a metallic foreign substance, a method of checking a minute voltage change (dV) during the formation process is used. However, the minute voltage change may also occur due to other factors (hereinafter referred to as a false defect), such as negative electrode charge depth or a non-uniform reaction, rather than due to a true defect. Accordingly, there is a demand for technological development that, in the formation process, discriminates whether the minute voltage change is due to a true defect or a false defect, so as to detect the defect of the battery.

According to embodiments of the present disclosure, by detecting a fault of the battery through discriminating whether a minute voltage change in the formation process is due to a true defect or a false defect, it is possible to prevent the battery from being discarded or the formation process from being repeated due to a false defect, thereby reducing costs and improving the yield of batteries.

However, the aspects and features of the present disclosure are not limited to those described above, and other aspects and features not expressly described herein will be clearly understood by a person skilled in the art from the description of example embodiments of the present disclosure described below.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, below.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A battery fault detection apparatus, comprising:
a charging/discharging circuit configured to charge and discharge a battery;
a voltage measuring circuit configured to measure a voltage;
a current measuring circuit configured to measure a current;
a memory; and
a processor connected to the charging/discharging circuit, the voltage measuring circuit, the current measuring circuit, and the memory,
wherein the processor is configured to:
in an aging process after charging and discharging the battery through the charging/discharging circuit, when a minute voltage change (dV) is detected, calculate a charge quantity (Q) based on a current value of a negative electrode plate included in the battery measured through the current measuring circuit,
calculate a rate of change of the voltage with respect to the charge quantity (dV/dQ) based on the charge quantity and a voltage value of the negative electrode plate measured through the voltage measuring circuit, resulting in a calculated rate of change of the voltage with respect to the charge quantity, and
detect a fault of the battery based on a curve (Q-dV/dQ curve) representing a relationship between the rate of change of the voltage with respect to the charge quantity and the charge quantity.

2. The battery fault detection apparatus as claimed in claim 1, wherein the processor is further configured to:
identify a value representing a sharpness of a second peak in a charging curve, and
if the value representing the sharpness is less than a predetermined amount, identify the battery as defective.

3. The battery fault detection apparatus as claimed in claim 1, wherein the processor is further configured to identify the battery as defective if an ion resistance obtained by measuring Electrochemical Impedance Spectroscopy is less than a predetermined amount.

4. The battery fault detection apparatus as claimed in claim 1, wherein the processor is further configured to:
obtain an image of the battery taken before the aging process and after a pre-charging process of the battery,
identify an area of a non-impregnated band of the negative electrode plate in the obtained image, and
if the area is less than a predetermined size, identify the battery as defective.

5. The battery fault detection apparatus as claimed in claim 1, wherein the processor is further configured to:
measure a 1S3 capacity of the negative electrode plate in a formation process of the battery, resulting in a measured 1S3 capacity, and
if the measured 1S3 capacity is equal to or greater than a predetermined size, identify the battery as defective.

6. The battery fault detection apparatus as claimed in claim 1, wherein the processor is further configured to:
based on the calculated rate of change of the voltage with respect to the charge quantity, calculate an available Li capacity, an uncharged capacity of the negative electrode plate, and an undischarged capacity of the negative electrode plate, and
if the available Li capacity is less than a predetermined first amount, the uncharged capacity of the negative electrode plate is equal to or greater than a predetermined second amount, and the undischarged capacity of the negative electrode plate is less than a predetermined third amount, identify the battery as defective.

7. The battery fault detection apparatus as claimed in claim 1, wherein the processor is further configured to:
measure a charging capacity of the battery and measure a discharging capacity of the battery,
calculate an efficiency of the battery based on the charging capacity of the battery and the discharging capacity of the battery, and
if the efficiency of the battery is equal to or greater than a predetermined amount, identify the battery as defective.

8. The battery fault detection apparatus as claimed in claim 1, wherein the processor is further configured to:
in a discharging curve, identify a value representing a sharpness of a peak that occurs after a peak caused by silicon manifestation, and
if the value representing the sharpness is equal to or greater than a predetermined amount, identify the battery as defective.

9. The battery fault detection apparatus as claimed in claim 1, wherein the processor is further configured to:
when charging of the battery is completed, measure a maximum charging voltage of the negative electrode plate, resulting in a measured maximum charging voltage, and
if the measured maximum charging voltage is equal to or greater than a predetermined amount, identify the battery as defective.

10. The battery fault detection apparatus as claimed in claim 1, wherein the processor is further configured to:
when discharging of the battery is completed, measure a quantity of electric charges released in a discharging process, resulting in a measured quantity of electric charges,
identify an available Si capacity based on the measured quantity of electric charges, and
if the available Si capacity is equal to or greater than a predetermined amount, identify the battery as defective.

11. A method for detecting fault of a battery, the method comprising:
in an aging process after charging and discharging the battery through a charging/discharging circuit, when a minute voltage change (dV) is detected, calculating a charge quantity (Q) based on a current value of a negative electrode plate included in the battery measured through a current measuring circuit;
calculating a rate of change of a voltage with respect to the charge quantity (dV/dQ) based on the charge quantity and a voltage value of the negative electrode plate measured through a voltage measuring circuit, resulting in a calculated rate of change of the voltage with respect to the charge quantity; and
detecting a fault of the battery based on a Q-dV/dQ curve representing a relationship between the rate of change of the voltage with respect to the charge quantity and the charge quantity.

12. The method for detecting fault of a battery as claimed in claim 11, wherein detecting the fault of the battery comprises:
identifying a value representing a sharpness of a second peak in a charging curve; and
identifying the battery as defective if the value representing the sharpness is less than a predetermined amount.

13. The method for detecting fault of a battery as claimed in claim 11, further comprising identifying the battery as defective if an ion resistance obtained by measuring Electrochemical Impedance Spectroscopy is less than a predetermined amount.

14. The method for detecting fault of a battery as claimed in claim 11, further comprising:
before an aging process and after a pre-charging process of the battery, obtaining an image of the battery;
identifying an area of a non-impregnated band of the negative electrode plate in the image; and
identifying the battery as defective if the area is less than a predetermined size.

15. The method for detecting fault of a battery as claimed in claim 11, further comprising:
measuring a 1S3 capacity of the negative electrode plate in a formation process of the battery, resulting in a measured 1S3 capacity; and
identifying the battery as defective if the measured 1S3 capacity is equal to or greater than a predetermined amount.

16. The method for detecting fault of a battery as claimed in claim 11, further comprising:
calculating an available Li capacity, an uncharged capacity of the negative electrode plate, and an undischarged capacity of the negative electrode plate based on the calculated rate of change of the voltage with respect to the charge quantity; and
identifying the battery as defective if the available Li capacity is less than a predetermined first amount, the uncharged capacity of the negative electrode plate is equal to or greater than a predetermined second amount, and the undischarged capacity of the negative electrode plate is less than a predetermined third amount.

17. The method for detecting fault of a battery as claimed in claim 11, further comprising:
measuring a charging capacity of the battery and a discharging capacity of the battery;
calculating an efficiency of the battery based on the charging capacity of the battery and the discharging capacity of the battery; and
identifying the battery as defective if the efficiency of the battery is equal to or greater than a predetermined amount.

18. The method for detecting fault of a battery as claimed in claim 11, wherein detecting the fault of the battery comprises:
identifying a value representing a sharpness of a peak that occurs after a peak caused by silicon manifestation in a discharging curve; and
identifying that the battery is defective if the value representing the sharpness is equal to or greater than a predetermined amount.

19. The method for detecting fault of a battery as claimed in claim 11, further comprising:
measuring a maximum charging voltage of the negative electrode plate when charging of the battery is completed, resulting in a measured maximum charging voltage; and
identifying the battery as defective if the measured maximum charging voltage is equal to or greater than a predetermined amount.

20. The method for detecting fault of a battery as claimed in claim 11, further comprising:
measuring a quantity of electric charges released during a discharging process when discharging of the battery is completed, resulting in a measured quantity of electric charges;
identifying an available Si capacity based on the measured quantity of electric charges; and
identifying the battery as defective if the available Si capacity is equal to or greater than a predetermined amount.
